(19) United States
(12) Patent Application Publication
(10) Pub. No.: US 2024/0297161 A1
(43) Pub. Date: Sep. 5, 2024

(54) DISPLAY PANEL AND DISPLAY DEVICE

(71) Applicant: Tianma Advanced Display Technology Institute (Xiamen) Co.,Ltd., Xiamen (CN)

(72) Inventor: Feng WANG, Xiamen (CN)

(73) Assignee: Tianma Advanced Display Technology Institute (Xiamen) Co.,Ltd., Xiamen (CN)

(21) Appl. No.: 18/662,294

(22) Filed: May 13, 2024

(30) Foreign Application Priority Data
Oct. 31, 2023 (CN) 202311438707.6

(51) Int. Cl. H01L 25/075; H01L 33/58

(52) U.S. Cl. CPC H01L 25/0753; H01L 33/58

(57) ABSTRACT

A display panel and a display device, and the display panel includes: the substrate including a display area; the display area includes micro light emitting devices located on the same side of the substrate, a first convex portion and a black film layer; and at least part of the orthographic projection of the black film layer on the plane of the substrate is located between orthographic projections of two adjacent micro light emitting devices on the plane of the substrate.

### CROSS-REFERENCE TO RELATED DISCLOSURE

The present disclosure claims priority to Chinese Patent Application No. 202311438707.6, filed on Oct. 31, 2023, the content of which is incorporated herein by reference in its entirety.

### TECHNICAL FIELD

The present disclosure relates to a display panel and a display device.

### BACKGROUND

Small-sized LED display technology generally refers to a technology in which a display array is formed using LED chips having a size less than 200 μm. The small-size LED chips include Micro LED chips and Mini LED chips. Since small-size LED chips have advantages such as self-light emitting, small size, light weight, high brightness, long service life, low power consumption, and fast response time, LED display technology has attracted more and more attention.

However, current display panels including small-size LEDs have a problem of high screen reflectivity.

### SUMMARY

In view of this, the present disclosure provides a display panel and a display device, so as to reduce the reflectivity of the display panel.

In a first aspect, embodiments of the disclosure provide a display panel, including:
a substrate, including a display area;
the display area includes a micro light emitting device, a first convex portion and a black film layer located on a same side of the substrate;
at least part of an orthographic projection of the black film layer on the plane of the substrate between orthographic projections of two adjacent micro light emitting devices on the plane of the substrate.

In a second aspect, an embodiment of the present disclosure provides a display device including the above display panel.

### BRIEF DESCRIPTION OF DRAWINGS

In order to describe the technical solutions in the embodiments of the present application more clearly, the drawings which are needed in the description of the embodiments will be briefly introduced as follows. The drawings in the following description are only some of the embodiments of the present application, and for those of ordinarily skilled in the art, other drawings can also be obtained in accordance with these drawings.

FIG. 1 is a schematic cross-sectional view of a display area of a display panel according to an embodiment of the present disclosure;

FIG. 2 is a schematic top view of a display area of a display panel according to an embodiment of the present disclosure;

FIG. 3 is a schematic top view of a display area of another display panel according to an embodiment of the present disclosure;

FIG. 4 is a schematic top view of a display area of another display panel according to an embodiment of the present disclosure;

FIG. 5 is a schematic top view of a display area of another display panel according to an embodiment of the present disclosure;

FIG. 6 is a schematic top view of a display area of another display panel according to an embodiment of the present disclosure;

FIG. 7 is a schematic top view of a display area of another display panel according to an embodiment of the present disclosure;

FIG. 8 is a schematic top view of a display area of another display panel according to an embodiment of the present disclosure;

FIG. 9 is a schematic top view of a display area of another display panel according to an embodiment of the present disclosure;

FIG. 10 is a schematic top view of a display area of another display panel according to an embodiment of the present disclosure;

FIG. 11 is a schematic top view of a display area of another display panel according to an embodiment of the present disclosure;

FIG. 12 is a schematic cross-sectional view of a display area of another display panel according to an embodiment of the present disclosure;

FIG. 13 is a schematic top view of a display panel according to an embodiment of the present disclosure;

FIG. 14 is a schematic top view of another display panel according to an embodiment of the present disclosure;

FIG. 15 is a schematic cross-sectional view of a display panel according to an embodiment of the present disclosure;

FIG. 16 is a schematic diagram of a display device according to an embodiment of the present disclosure.

### DESCRIPTION OF EMBODIMENTS

In order to better understand the technical solutions of the present disclosure, the following is a detailed description of embodiments of the present disclosure with reference to the accompanying drawings.

It should be made clear that the embodiments described are only part of rather than all of the embodiments of the present disclosure. All other embodiments acquired by those of ordinary skill in the art based on the described embodiments of the present disclosure shall fall within the protection scope of the present disclosure.

The terms used in the embodiments of the present disclosure are merely for the purpose of describing specific embodiments, but not intended to limit the present disclosure. The singular forms of “a”, “an” and “the” used in the embodiments of the present disclosure and the appended claims are also intended to indicate plural forms, unless clearly indicating others.

It should be understood that the term “and/or” used herein is merely an association relationship describing associated objects, indicating that there may be three relationships, for example, A and/or B may indicate that three cases, i.e., A existing individually, A and B existing simultaneously, B existing individually. In addition, the character “/” herein generally indicates an “or” relationship between the associated objects.

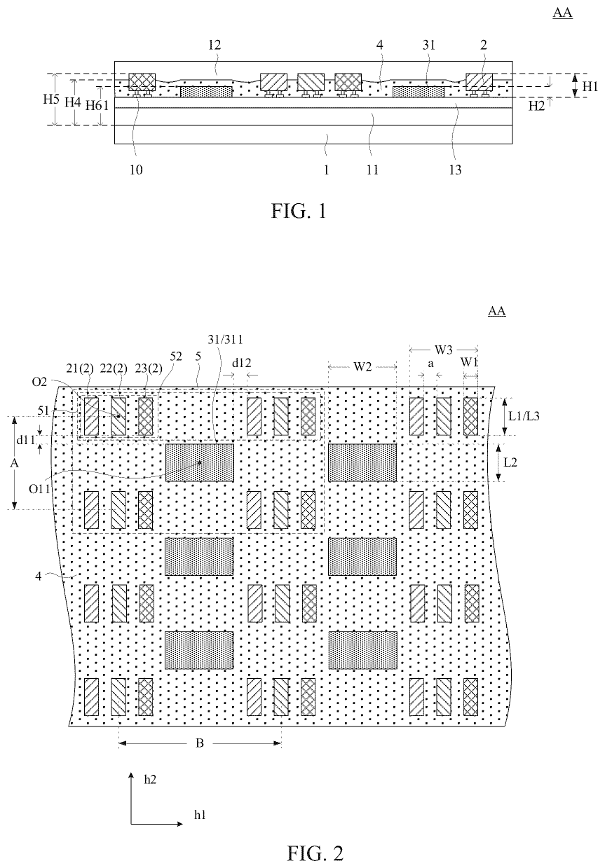

An embodiment of the present disclosure provides a display panel, as shown in FIG. 1, FIG. 1 is a schematic cross-sectional view of a display area of the display panel according to an embodiment of the present disclosure, the display panel includes a substrate 1, and the substrate 1 includes a display area AA; the display area AA includes micro light-emitting devices 2, first convex portion 31, and a black film layer 4 located on a same side of the substrate 1; the micro light-emitting devices 2 include Micro LEDs and/or Mini LEDs; and at least a part of an orthographic projection of the black film layer 4 on a plane where the substrate 1 is located is located between orthographic projections of two adjacent micro light-emitting devices 2 on the plane where the substrate 1 is located. The black film layer 4 may absorb ambient light, thereby reducing the intensity of the ambient light reflected by the display panel, and also playing a role in reducing the reflectivity of the display panel.

Exemplarily, as shown in FIG. 1, the display panel further includes a driving layer 11, an encapsulation layer 12 and a planarization layer 13. The driving layer 11 is located on a side of the substrate 1. The driving layer 11 includes a pixel driving circuit (not shown), and the pixel driving circuit is electrically connected to the micro light emitting device 2 through the bonding electrode 10. The encapsulation layer 12 is located on a side of the black film layer 4 away from the substrate 1, and the planarization layer 13 is located on a side of the driving layer 11 away from the substrate 1.

When manufacturing the display panel, the driving layer 11, the planarization layer 13, and the first convex portion 31 may be first formed on a side of the substrate 1. Then, the micro light emitting device 2 is transferred to a side of the planarization layer 13 away from the substrate 1, and the micro light emitting device 2 is bonded to the pixel driving circuit in the driving layer 11 through the bonding electrode 10. Then, a black liquid is provided on a side of the planarization layer 13 away from the substrate 1. The black liquid can be flattened and dried to form the black film layer 4, and then the encapsulation layer 12 can be prepared.

Exemplarily, the black liquid may be prepared by an inkjet printing process. The first convex portion 31 may be formed by a photolithography process.

In the process of implementing the embodiments of the present disclosure, the applicants have found that after the micro light emitting device 2 is transferred to the side of the planarization layer 13 away from the substrate 1, there is a distance between the micro light emitting device 2 and the surface of the planarization layer 13. The micro light emitting device 2 will form a strong capillary action on the black liquid, resulting in a large difference between the thickness of the black liquid at the position close to the micro light emitting device 2 and the thickness of the black liquid at other positions, and then resulting in a non-uniform thickness of the black film layer 4 formed later, affecting the ink color consistency of the black film layer 4 at different positions.

In some embodiments of the present disclosure, by providing the first convex portion 31 in the display area AA, the thickness of the black liquid near the position where the first convex portion 31 is located may be increased by using the capillary action of the first convex portion 31 on the black liquid, so that the thickness of the black liquid at the position close to the first convex portion 31 tends to be consistent with the thickness of the black liquid at the position close to the micro light emitting device 2, thereby avoiding the problem of the thickness of the black film layer 4 formed by the black liquid at the position close to the micro light emitting device 2 being large and the thickness of the black film layer 4 at the position away from the micro light emitting device 2 being small after the black liquid is dried. That is, based on the arrangement provided by the embodiment of the present disclosure, while the black film layer 4 is provided to reduce the reflectivity of the display panel, the thickness uniformity of the black film layer 4 at different positions can also be ensured, thereby improving the ink color consistency of the black film layer 4 at different positions and making the reflectivity of the display panel at different positions tend to be consistent, which is beneficial to improving the display effect of the display panel.

Exemplarily, as shown in FIG. 2, FIG. 2 is a schematic top view of a display area of a display panel according to an embodiment of the present disclosure. The display area AA includes a plurality of pixel unit groups 5 arranged along a first direction h1 and a second direction h2, each pixel unit group 5 includes two pixel row groups 51 arranged along the second direction h2, each pixel row group 51 includes two pixel units 52 arranged along the first direction h1, and each pixel unit 52 includes at least two micro light emitting devices 2 of different colors arranged along the first direction h1. FIG. 2 illustrates the pixel unit 52 including a first color micro light emitting device 21, a second color micro light emitting device 22, and a third color light emitting device 23. The first color micro light emitting device 21, the second color micro light emitting device 22 and the third color light emitting device 23 are different, so that the display panel realizes full-color display. Exemplarily, the first color, the second color and the third color include red, green and blue. The first direction h1 and the second direction h2 intersect. FIG. 2 shows the first direction h1 and the second direction h2 perpendicular to each other.

It should be noted that the pixel unit 52 shown in FIG. 2 includes three micro light emitting devices 2 of different colors arranged along the first direction h1 for illustration only. The arrangement rule of the micro light emitting devices 2 in the pixel unit 52 may be adjusted according to different display requirements, for example, when the pixel unit 52 includes three micro light emitting devices 2 of different colors, two of the micro light emitting devices 2 may also be arranged along the first direction h1, and the other micro light emitting device 2 and the two micro light emitting devices 2 are staggered from each other in the first direction h1. That is, the connecting lines of the three micro light emitting devices 2 of different colors are triangular.

Exemplarily, as shown in FIG. 2, the display area AA includes a first convex portion group 311, and the first convex portion group 311 includes at least one first convex portion 31. In some embodiments of the present disclosure, distances between the first convex portion group 311 and four pixel units 52 in the pixel unit group 5 are equal. The distance between the first convex portion group 311 and the pixel unit 52 refers to the distance between the geometric center O11 of the first convex portion group 311 and the geometric center O2 of the pixel unit 52. In some embodiments of the present disclosure, by providing the first convex portion group 311 including at least one first convex portion 31 at the center of the pixel unit group 5, on one hand, the thickness of the black film layer 4 at the position close to the center of the pixel unit group 5 can be increased to be close to the thickness near each micro light emitting device 2 in the corresponding pixel unit group 5. On the other hand, the thickness distribution rule of the black film layer 4 at the position near each pixel unit 52 in one pixel unit group 5 can tend to be consistent, which is beneficial to improve the display consistency.

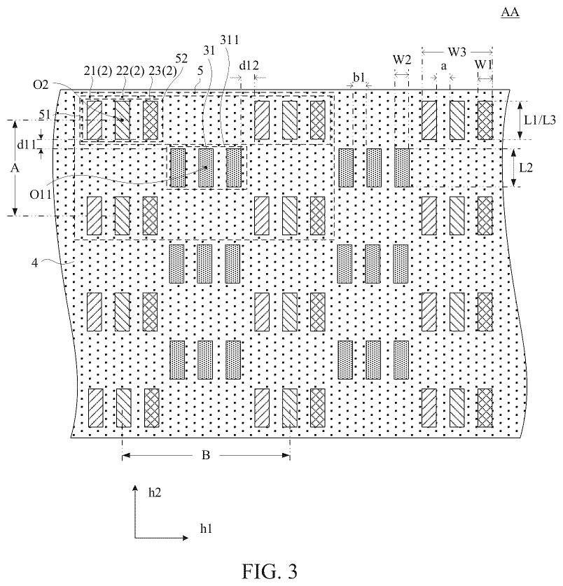

FIG. 2 illustrates that the first convex portion group 311 includes one first convex portion 31, the geometric center O11 of the first convex portion group 311 is the geometric center of the first convex portion 31. Alternatively, in an embodiment of the present disclosure, the first convex portion group 311 may include at least two first convex portions 31 arranged along the first direction h1, and as shown in FIG. 3, FIG. 3 is a schematic top view of a display area of another display panel according to an embodiment of the present disclosure, the first convex portion group 311 includes three first convex portions 31 arranged along the first direction h1 as an example. The geometric center O11 of the first convex portion group 311 is the geometric center of the centrally provided first convex portion 31.

As shown in FIG. 3, a distance b1 between two adjacent first protrusions 31 in the first convex portion group 311 is equal to a distance a1 between two adjacent micro light emitting devices 2 in the pixel unit 52. Based on this arrangement, while the thickness consistency of the black film layer 4 at different positions in the display area AA is equalized by the capillary action of the first convex portion 31 in the first convex portion group 311, the flow characteristic of the black liquid between two adjacent first convex portions 31 in the first convex portion group 311 tends to be consistent with the flow characteristic between two adjacent micro light emitting devices 2 in the pixel unit 52, so that the thickness consistency of the black film layer 4 can be further improved.

Optionally, in some embodiments of the present disclosure, the first convex portion 31 may be provided between two adjacent pixel unit groups 5 in the first direction h1, and/or, the first convex portion 31 may be provided between two adjacent pixel unit groups 5 in the second direction h2, and in FIG. 2 and FIG. 3, the first convex portion 31 may be provided between two adjacent pixel unit groups 5 in the first direction h1 and between two adjacent pixel unit groups 5 in the second direction h2 as an example, so provided, the thickness of the black film layer 4 in a plurality of different areas in the display area AA can be made uniform.

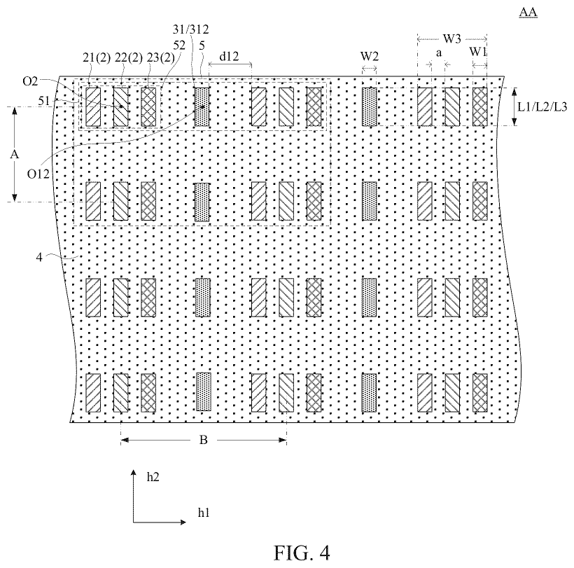

Exemplarily, as shown in FIG. 4, which is a schematic top view of a display area of another display panel according to an embodiment of the present disclosure, the display area AA further includes a second convex portion group 312, the second convex portion group 312 is located between two pixel units 52 in the same pixel row group 51, and distances between the second convex portion group 312 and the two pixel units 52 in the same pixel row group 51 are equal. The distance between the second convex portion group 312 and the pixel unit 52 in the pixel row group 51 refers to a distance between a geometric center O12 of the second convex portion group 312 and a geometric center O2 of the pixel unit 52. The second convex portion 312 includes at least one first convex portion 31. In some embodiments of the present disclosure, by providing the second convex portion group 312 including the at least one first convex portion 31 at the center of the pixel row group 51, on one hand, the thickness of the black film layer 4 at the position close to the center of the pixel row group 51 can be increased to be close to the thickness near each micro light emitting device 2 in the corresponding pixel row group 51. On the other hand, the thickness distribution rule of the black film layer 4 at the position near each pixel unit 52 in one pixel row group 51 can tend to be consistent, which is beneficial for improving the display consistency.

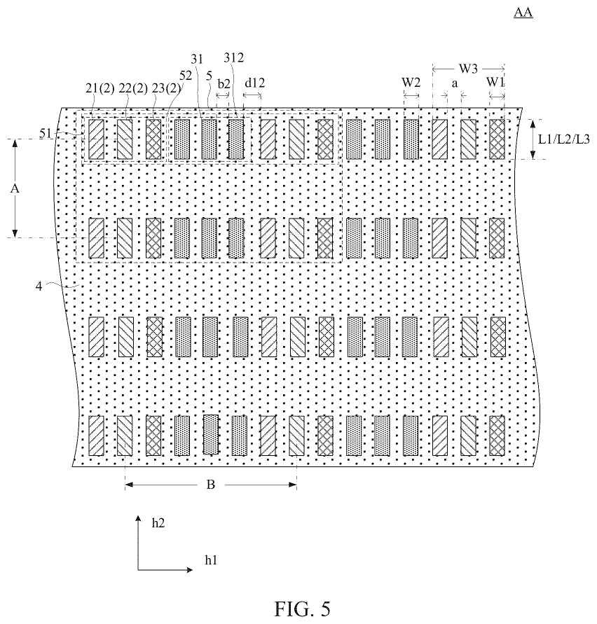

FIG. 4 illustrates the second convex portion group 312 including one first convex portion 31 as an example, or, the embodiment of the present disclosure may also cause the second convex portion group 312 to include at least two first convex portions 31 arranged along the first direction h1, as shown in conjunction with FIG. 5, which is a schematic top view of a display area of another display panel according to the embodiment of the present disclosure, the second convex portion group 312 is illustrated to include three first convex portion 31 arranged along the first direction h1. As shown in FIG. 5, a distance b2 between two adjacent first convex portions 31 in the second convex portion group 312 is equal to a distance a1 between two adjacent micro light emitting devices 2 in the pixel unit 52. Based on this arrangement, while the thickness consistency of the black film layer 4 at different positions in the display area AA is equalized by the capillary action of the first convex portion 31 in the second convex portion group 312, the flow characteristic of the black liquid between two adjacent first convex portions 31 in the second convex portion group 312 tends to be consistent with the flow characteristic between two adjacent micro light emitting devices 2 in the pixel unit 52, so that the thickness consistency of the black film layer 4 can be further improved.

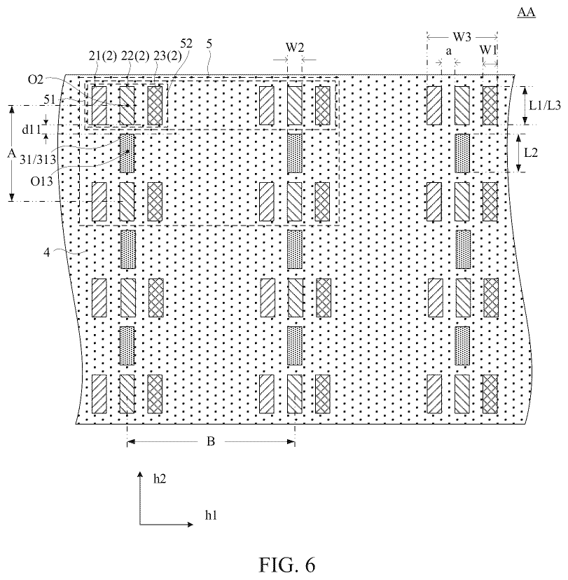

Exemplarily, as shown in FIG. 6, which is a schematic top view of a display area of another display panel according to an embodiment of the present disclosure, the display area AA further includes a third convex portion group 313, the third convex portion group 313 is located between two adjacent pixel units 52 in the second direction h2 in two adjacent pixel row groups 51, and distances between the third convex portion group 313 and the two pixel row groups 51 are equal. The distance between the third convex portion group 313 and the pixel unit 52 refers to a distance between a geometric center O13 of the third convex portion group 313 and a geometric center O2 of the pixel unit 52. The third convex portion 313 includes at least one first convex portion 31. In some embodiments of the present disclosure, by providing the third convex portion group 313 including at least one first convex portion 31 at the center of two adjacent pixel units 52 in the second direction h2 in two adjacent pixel row groups 51, on one hand, the thickness of the black film layer 4 at the position close to the center of two adjacent pixel units 52 in the second direction h2 in two adjacent pixel row groups 51 can be increased to be close to the thickness at the position close to the micro light emitting device 2. On the other hand, the thickness distribution rule of the black film layer 4 at the position close to two adjacent pixel units 52 in the second direction h2 in two adjacent pixel row groups 51 can tend to be consistent, which is beneficial to improving the display consistency.

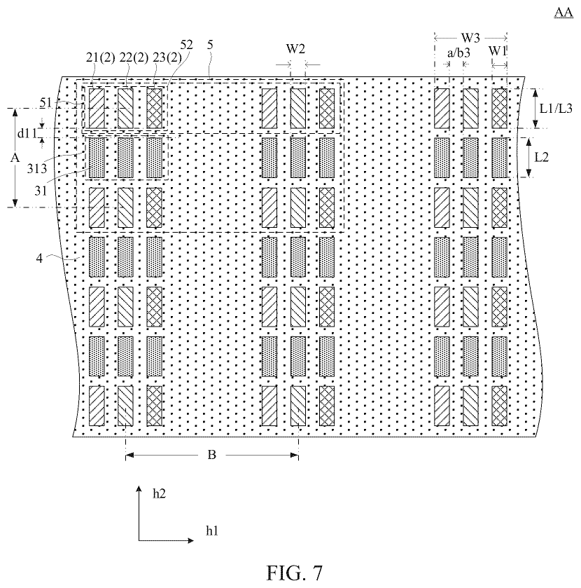

In FIG. 6, the third convex portion group 313 includes one first convex portion 31 as an example, or the third convex portion group 313 may include at least two first convex portions 31 arranged along the first direction h1. Exemplarily, an embodiment of the present disclosure may cause the number of first convex portion 31 in the third convex portion group 313 to be the same as the number of micro light emitting devices 2 in the pixel unit 52. In conjunction with FIG. 7, FIG. 7 is a schematic top view of a display area of another display panel according to an embodiment of the present disclosure, in which the pixel unit 52 includes three micro light emitting devices 2 arranged along the first direction h1, and the third convex portion group 313 includes three first convex portion 31 arranged along the first direction h1 as an example. The first convex portion 31 in the third convex portion group 313 and the micro light emitting device 2 closest to each other in the pixel unit 52 are arranged along the second direction h2.

Optionally, as shown in FIG. 7, a distance b3 between two adjacent first convex portions 31 in the third convex portion group 313 is equal to a distance a1 between two adjacent micro light emitting devices 2 in the pixel unit 52. Based on this arrangement, while the thickness consistency of the black film layer 4 at different positions in the display area AA is equalized by the capillary action of the first convex portion 31 in the third convex portion group 313, the flow characteristic of the black liquid between two adjacent first convex portions 31 in the third convex portion group 313 tends to be consistent with the flow characteristic between two adjacent micro light emitting devices 2 in the pixel unit 52, so that the thickness consistency of the black film layer 4 can be further improved.

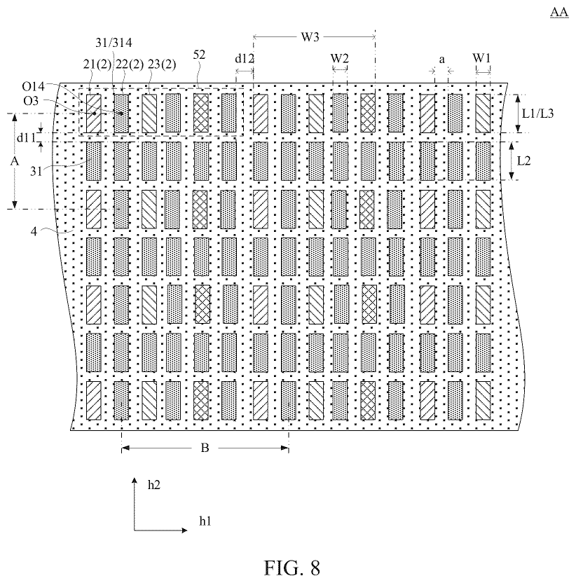

As shown in FIG. 8, FIG. 8 is a schematic top view of a display area of another display panel according to an embodiment of the present disclosure, the display area AA further includes a fourth convex portion group 314, the fourth convex portion group 314 includes at least one first convex portion 31, the first convex portion 31 in the fourth convex portion group 314 is located between two adjacent micro light emitting devices 2 in one pixel unit 52, and distances between the fourth convex portion group 314 and the two adjacent micro light emitting devices 2 in the pixel unit 52 are equal. The distance between the fourth convex portion group 314 and the micro light emitting device 2 refers to the distance between the geometric center O14 of the fourth convex portion group 314 and the geometric center O3 of the micro light emitting device 2. FIG. 8 shows that the first convex portion group 311 includes one first convex portion 31. In some embodiments of the present disclosure, by providing the fourth convex portion group 314 including one first convex portion 31 at the center of two adjacent micro light emitting devices 2 in one pixel unit 52, on one hand, the thickness of the black film layer 4 at the position close to the center of two adjacent micro light emitting devices 2 in one pixel unit 52 can be increased to be close to the thickness at the position close to the micro light emitting device 2, and on the other hand, the thickness distribution rule of the black film layer 4 at the position close to each micro light emitting device 2 in one pixel unit 52 can tend to be consistent, which is beneficial to improve the display consistency.

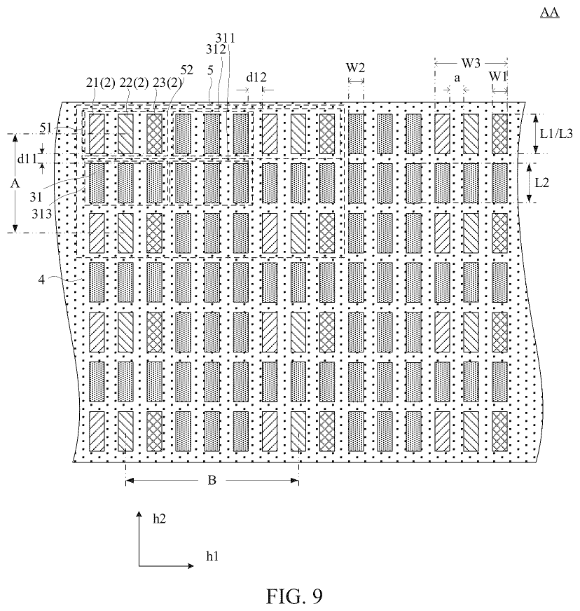

Exemplarily, in some embodiments of the present disclosure, a combination of at least two of the first convex portion group 311, the second convex portion group 312, the third convex portion group 313 and the fourth convex portion group 314 may be provided in the display area AA. FIG. 9 is a schematic top view of a display area of another display panel according to an embodiment of the present disclosure. Taking the display area AA including a first convex portion group 311, a second convex portion group 312, and a third convex portion group 313 as an example, based on this arrangement, the density of the first convex portion 31 in the display area AA can be increased, which is conducive to enhancing the capillary action of the first convex portion 31 on the black liquid during the preparation process of the display panel, and thus the consistency of the thickness of the black film layer 4 formed by the black liquid can be further improved.

Optionally, as shown in FIG. 2, FIG. 3, FIG. 4, FIG. 5, FIG. 8 and FIG. 9, In some embodiments of the present disclosure, the distance d12 between the first convex portion 31 and the closest micro light emitting device 2 in the first direction h1 may satisfy: W1/4≤d12≤B/2−W1. The distance d12 between the first convex portion 31 and the closest micro light emitting device 2 in the first direction h1 refers to the distance between the edge of the first convex portion 31 and the edge of the closest micro light emitting device 2. In addition, as shown in FIG. 2, FIG. 3, FIG. 6, FIG. 7, FIG. 8 and FIG. 9, in some embodiments of the present disclosure, the distance d11 between the first convex portion 31 and the closest micro light emitting device 2 in the second direction h2 may satisfy: L1/4≤d11≤A1/2−L1. The distance d11 between the first convex portion 31 and the closest micro light emitting device 2 in the second direction h2 refers to the distance between the edge of the first convex portion 31 and the edge of the closest micro light emitting device 2.

A1 is a distance between centers of two adjacent pixel units 52 in the second direction h2; B is a distance between centers of two adjacent pixel units 52 in the first direction h1; L1 is a length of the single micro light emitting device 2 in the second direction h2; and W1 is a length of the single micro light emitting device 2 in the first direction h1. In some embodiments of the present disclosure, by providing the distance d12 between the first convex portion 31 and the micro light emitting device 2 closest to the first convex portion 31 in the first direction h1 to be d12≥W1/4, and providing the distance d11 between the first convex portion 31 and the micro light emitting device 2 closest to the first convex portion 31 in the second direction h2 to be d11≥L1/4, it is possible to avoid providing the distance between the first convex portion 31 and the micro light emitting device 2 too small. When transferring the micro light emitting device 2, it is possible to reduce the possibility that the micro light emitting device 2 conflicts with the first convex portion 31 due to errors and the like, which may reduce the requirement on the process precision, and is beneficial to improving the process yield of the display panel. In addition, in the embodiments of the present disclosure, by providing d12≤B/2−W1 and d11≤A1/2−L1, the distance between the first convex portion 31 and the micro light emitting device 2 can avoid to be too large, which is beneficial to improving the thickness consistency of the black film layer 4 at a plurality of positions different from the micro light emitting device 2 by using the first convex portion 31.

Optionally, as shown in FIG. 2, FIG. 3, FIG. 4, FIG. 5, FIG. 8 and FIG. 9, in this embodiment of the present disclosure, d12=a1, a1 is a distance between two adjacent micro light emitting devices 2 in the pixel unit 52 in the first direction h1. In some embodiments of the present disclosure, the distance d12 between the first protrusion 31 and the micro light emitting device 2 closest to the first convex portion 31 in the first direction h1 is provided to be equal to the distance a1 between two adjacent micro light emitting devices 2 in the pixel unit 52 in the first direction h1, so that the thickness consistency of the black film layer 4 at different positions in the display area AA is balanced by using the capillary action of the first convex portion 31. Meanwhile, the flow characteristic of the black liquid between the first convex portion 31 and the adjacent micro light emitting device 2 tends to be consistent with the flow characteristic of the black liquid between two adjacent micro light emitting devices 2 in the pixel unit 52, thereby further improving the thickness consistency of the black film layer 4.

Exemplarily, as shown in FIG. 2, FIG. 3, FIG. 4, FIG. 5, FIG. 6, FIG. 7, FIG. 8 and FIG. 9, the length of the pixel unit 52 in the first direction h1 is W3, the length of the pixel unit 52 in the second direction h2 is L3, the length of the micro light emitting device 2 in the first direction h1 is W1, and the length of the micro light emitting device 2 in the second direction h2 is L1; FIG. 2, FIG. 3, FIG. 4, FIG. 5, FIG. 6, FIG. 7, FIG. 8 and FIG. 9 are all illustrated by L1=L3. A length of the first convex portion 31 in the first direction h1 is W2, and a length of the first convex portion 31 in the second direction h2 is L2, W1/2≤W2≤W3; L1/2≤L2≤L3.

In some embodiments of the present disclosure, by providing W2≥W1/2 and L2≥L1/2, the process difficulty of the first convex portion 31 can be reduced, and the preparation of the first convex portion 31 is facilitated. Exemplarily, the first convex portion 31 may adopt a photolithography process. In addition, In some embodiments of the present disclosure, W2≤W3, and L2≤L3, on one hand, it can be ensured that the first convex portion 31 has a strong capillary action on the black liquid, and on the other hand, a flow path can also be reserved for the black liquid, so as to avoid excessive size of the first convex portion 31 from blocking diffusion and filling of the liquid to a area between two adjacent micro light emitting devices 2.

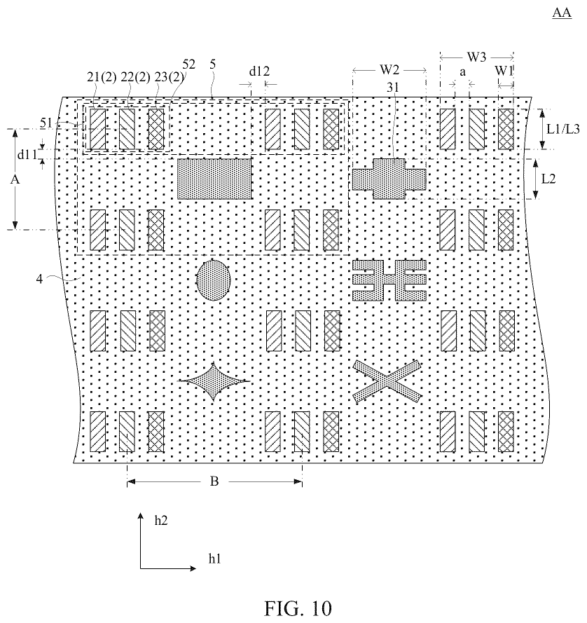

Exemplarily, the shape of the first convex portion 31 includes a central symmetric shape. The central symmetric shape includes a rectangle as shown in FIG. 2, FIG. 3, FIG. 4, FIG. 5, FIG. 6, FIG. 7, FIG. 8, and FIG. 9, or in an embodiment of the present disclosure, the shape of the first convex portion 31 may be provided to be a plurality of other central symmetric shape except the rectangle, as shown in FIG. 10, which is a schematic top view of a display area of another display panel according to an embodiment of the present disclosure, shapes of the first convex portion 31 located at different positions are designed to be different central symmetric shape as an example.

Optionally, as shown in FIG. 1, a distance between a surface of the micro light emitting device 2 away from the planarization layer 13 and the planarization layer 13 is H1, and a distance between a surface of the first convex portion 31 away from the planarization layer 13 and the planarization layer 13 is H2, H1/3≤H2≤H1/2. In some embodiments of the present disclosure, by providing H2≥H1/3, it can be ensured that the first convex portion 31 has a strong capillary action on the liquid corresponding to the black film layer 4. In addition, In some embodiments of the present disclosure, by providing H2≤H1/2, the distance between the surface of the first convex portion 31 away from the planarization layer 13 and the planarization layer 13 can avoid to be too large. After the black liquid is leveled, the thickness of the part of the prepared black film layer 4 located on the side of the first convex portion 31 away from the planarization layer 13 can avoid to be too small, which is beneficial to improving the black consistency of the black film layer 4 at different positions of the display area AA and improving the display effect of the display panel.

Exemplarily, a distance between a surface of the first convex portion 31 in the first convex portion group 311 away from the planarization layer 13 and the planarization layer 13 is H21, a distance between a surface of the first convex portion 31 in the second convex portion group 312 away from the planarization layer 13 and the planarization layer 13 is H22, a distance between a surface of the first convex portion 31 in the third convex portion group 313 away from the planarization layer 13 and the planarization layer 13 is H23, and a distance between a surface of the first convex portion 31 in the fourth convex portion group 314 away from the planarization layer 13 and the planarization layer 13 is H24, An embodiment of the present disclosure may make H24≤H21, H24≤H22, H24≤H23, that is, the thickness of the first convex portion 31 in the fourth convex portion group 314 provided between two adjacent micro light emitting devices 2 within a pixel unit 52 is provided to be small, so as to ensure a smooth flow of the black liquid for forming the black film layer 4 between the two adjacent micro light emitting devices 2 in the preparation process of the display panel. Optionally, in this embodiment of this disclosure, H22≤H21, and H23≤H21.

In the preparation of the first convex portion 31, optionally, in some embodiments of the present disclosure, the planarization layer 13 and the first convex portion 31 may be formed simultaneously in the same process by using a half-grayscale mask, so as to simplify the manufacturing process of the display panel.

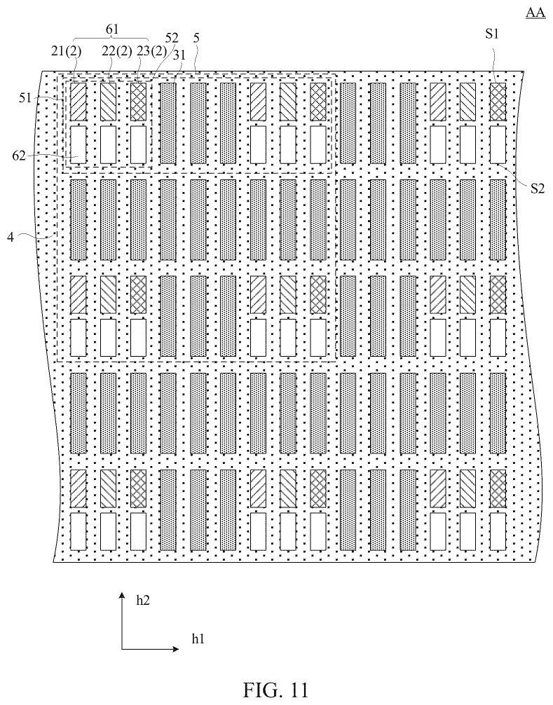

Exemplarily, as shown in FIG. 11, which is a schematic top view of a display area of another display panel according to an embodiment of the present disclosure, the display area AA includes an in-situ position 61 provided with a micro light emitting device 2 and a redundant position 62 corresponding to the micro light emitting device 2. Optionally, both the in-situ position 61 and the redundant position 62 are provided with the bonding electrode (not shown in FIG. 11), when the display panel is manufactured, after the micro light emitting device 2 is transferred to the surface of the planarization layer (not shown in FIG. 11) and electrically connected to the bonding electrode at the in-situ position 61, the display panel is tested. If the micro light emitting device 2 has a defective pixel, the connection between the micro light emitting device 2 at the in-situ position 61 and the corresponding bonding electrode is cut off, and another micro light emitting device 2 is bound at the corresponding redundant position 62, and in subsequent display, the micro light emitting device 2 at the redundant position 62 is used to emit light. The arrangement of the redundant position 62 can facilitate the repair of the defective pixel, which is beneficial to improve the process efficiency of the display panel.

In some embodiments of the present disclosure, the shape of the micro light emitting device 2 provided at the redundant position 62 and the color, shape and size of the micro light emitting device 2 at the in-situ position 61 are in one-to-one correspondence, and the redundant position 62 and the corresponding in-situ position 61 are provided adjacently. Taking FIG. 11 as an example, the pixel unit 52 includes three first color micro light emitting devices 21, three second color micro light emitting devices 22 and three third color micro light emitting devices 23 provided along the first direction h1. The redundant position 62 and the corresponding in-situ position 61 are adjacently provided in the second direction h2. The length of the pixel unit 52 in the second direction h2 is the distance between the edge S1 of the in-situ position 61 away from the corresponding redundant position 62 and the edge S2 of the redundant position 62 away from the corresponding in-situ position 61 in the second direction h2, that is, the area where the pixel unit 52 is located includes the area where the redundant position 62 corresponding to the micro light emitting device 2 is located.

Optionally, in some embodiments of the present disclosure, the first convex portion 31 may be provided between two adjacent redundant positions 62; and/or, the first convex portion 31 may be provided between the redundant position 62 and the adjacent micro light emitting device 2. In this way, the thickness of the black film layer 4 at the position near the first convex portion 31 and the thickness of the black film layer 4 at the position near the redundant position 62 tend to be consistent while improving the process efficiency of the display panel. In FIG. 11, a plurality of first convex portions 31 are provided in the display area AA, some of the first convex portions 31 are located between two adjacent redundant positions 62 in the first direction h1, and some of the first convex portions 31 are located between the redundant positions 62 and the adjacent micro light emitting devices 2 as examples. As shown in FIG. 11, the redundant positions 62 located on both sides of the first convex portion 31 and the micro light emitting device 2 may belong to different pixel units 52, respectively.

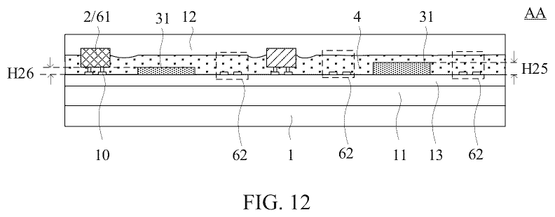

Exemplarily, as shown in FIG. 12, which is a schematic cross-sectional view of a display area of another display panel according to an embodiment of the present disclosure, a distance between a surface of the first convex portion 31 between two adjacent redundant positions 62 away from the planarization layer 13 and the planarization layer 13 is H25, and a distance between a surface of the first convex portion 31 between the redundant position 62 and the corresponding micro light emitting device 2 away from the planarization layer 13 and the planarization layer 13 is H26, H25>H26.

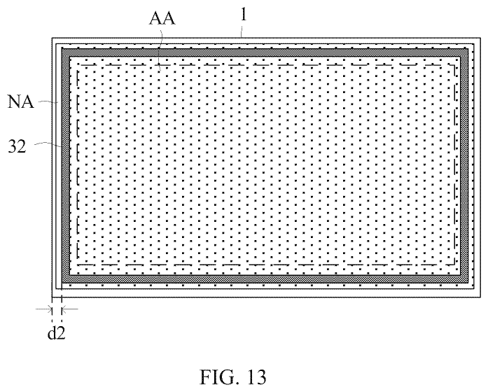

As shown in FIG. 13, which is a schematic top view of a display panel according to an embodiment of the present disclosure, the substrate 1 further includes a non-display area NA, and the non-display area NA includes a second convex portion 32. In the process of preparing the black film layer 4 by using the inkjet printing process, the second convex portion 32 has a capillary action on the black liquid, and the liquid drops printed to the edge of the display panel can flow back to a position near the second convex portion 32 under the capillary action of the second convex portion 32, thereby reducing the fluidity of the liquid at the edge of the display panel and preventing the liquid from flowing out of the display panel. After the printing is completed, the black film layer 4 at the position where the second convex portion 32 is located may level over time.

Exemplarily, the second convex portion 32 may be formed by screen printing or inkjet printing process. Specifically, when preparing the display panel, in some embodiments of the present disclosure, the second convex portion 32 may be mixed in the solvent first. Then, the liquid including the second convex portion 32 is coated on the surface of the driving layer by screen printing or inkjet printing process, and then the solvent in the liquid is removed by baking to form the second convex portion 32 in the non-display area NA of the substrate 1. Alternatively, the second convex portion 32 may be formed by a photolithography process. Exemplarily, in the embodiments of the present disclosure, the second convex portion 32 and the first convex portion 31 may be provided in the same layer, so as to simultaneously form the second convex portion 32 and the first convex portion 31 through the same patterning process, thereby simplifying the preparation process of the display panel.

Optionally, as shown in FIG. 13, the distance d2 between the second convex portion 32 and the edge of the display panel satisfies 10 μm≤d2≤20 μm, so that the black liquid can have a sufficiently large coverage area while the second protrusion 32 is used to prevent the black liquid from flowing out of the display panel, so that the black film layer 4 formed by the black liquid has a sufficiently large coverage area, thereby ensuring that multiple positions in the display panel have relatively low reflectivity.

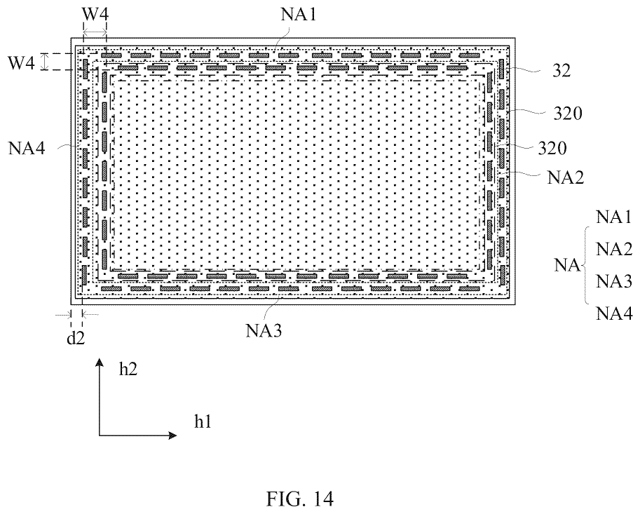

Exemplarily, as shown in FIG. 13, in some embodiments of the present disclosure, the second convex portion 32 may surround the display area AA to block overflow of the black liquid from multiple directions. Alternatively, as shown in FIG. 14, FIG. 14 is a schematic top view of another display panel according to an embodiment of the present disclosure, the non-display area NA includes a plurality of fifth convex portion groups 320, and the plurality of fifth convex portion groups 320 are arranged along a direction from the non-display area NA to the display area AA; the fifth convex portion group 320 includes a plurality of second convex portions 32 arranged along an extension direction of an edge of the display panel.

As shown in FIG. 14, one second convex portion 32 in the fifth convex portion group 320 at least partially overlaps two second convex portions 32 closest to the one second convex portion in the adjacent fifth convex portion group 320 in a third direction, and the third direction is parallel to the direction from the display area AA to the non-display area NA.

As shown in FIG. 14, the display panel includes a quadrilateral shape, a long side of the display panel is parallel to the first direction h1, a short side of the display panel is parallel to the second direction h2, and the non-display area NA includes a first non-display area NA1, a second non-display area NA2, a third non-display area NA3 and a fourth non-display area NA4 as an example. In the first non-display area NA1 and the third non-display area NA3, the third direction is parallel to the second direction h2, and in the second non-display area NA2 and the fourth non-display area NA4, the third direction is parallel to the first direction h1. In the process of preparing the black film layer 4 by using the inkjet printing process, the black liquid printed to the edge of the display panel flows through the gap between two adjacent second convex portions 32, and in an embodiment of the present disclosure, one second convex portion 32 in the fifth convex portion group 320 at least partially overlaps two second convex portions 32 closest to each other in the adjacent fifth convex portion group 320 in the third direction, so that the flow path of the black liquid can be extended, and the possibility that the black liquid overflows the display panel is further reduced.

Exemplarily, as shown in FIG. 14, a total width W4 of the plurality of fifth convex portion groups 320 satisfies: 25 μm≤W4≤35 μm. The total width of the fifth convex portion group 320 refers to a distance between an inner edge of the fifth convex portion group 320 close to the display area AA and an outer edge of the fifth convex portion group 320 away from the display area AA in the third direction. Based on this arrangement, while the black liquid is prevented from flowing out of the display panel, the width of the fifth convex portion group 320 avoids being too large, so as to reduce the width of the non-display area NA and realize the narrow frame design of the display panel.

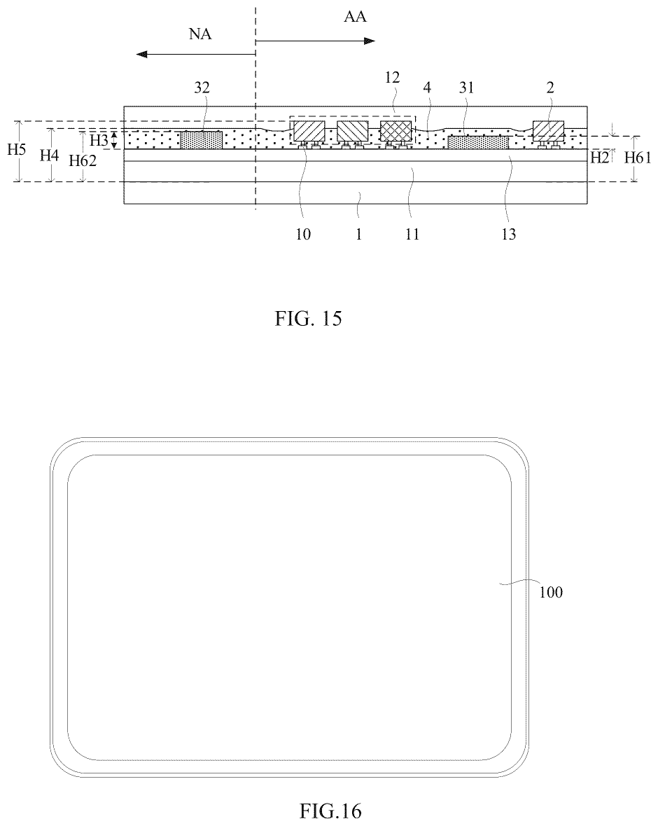

As shown in FIG. 15, which is a schematic cross-sectional view of a display panel according to an embodiment of the present disclosure, a distance H3 between a surface of the second convex portion 32 away from the planarization layer 13 and the planarization layer 13 is less than or equal to half of a distance H1 between a surface of the micro light emitting device 2 away from the planarization layer 13 and the planarization layer 13. In this way, the thickness of the black film layer 4 at the position close to the second convex portion 32 can avoid being too large caused by the capillary action of the second convex portion 32 on the black liquid.

Exemplarily, as shown in FIG. 15, in this embodiment of the present disclosure, H3>H2, a distance H3 between a surface of the second convex portion 32 away from the planarization layer 13 and the planarization layer 13, that is, a height H3 of the second convex portion, and a distance H2 between a surface of the first convex portion 31 away from the planarization layer 13 and the planarization layer 13, that is, a height H2 of the first convex portion. In the present embodiment, by providing the height of the second convex portion to be greater than the height of the first convex portion, on one hand, the second convex portion 32 in the edge area solves the capillary action of the black liquid in the edge area to cause the thickness of the black film layer to be non-uniform. On the other hand, the second convex portion 32 with a larger height is used in the edge area to perform a blocking action, so as to prevent the black liquid from covering the edge of the display panel substrate due to too large fluidity.

Optionally, as shown in FIG. 1 and FIG. 15, the distance H4 between the black film layer 4 and the substrate 1 is less than or equal to the distance H5 between the surface of the side of the micro light emitting device 2 away from the substrate 1 and the substrate 1. The distance between the black film layer 4 and the substrate 1 refers to the distance between the surface of the side of the black film layer 4 away from the substrate 1 and the substrate 1. This arrangement can prevent the black film layer 4 from blocking the emergent light of the micro light emitting device 2, and can ensure sufficient brightness of the display panel.

Exemplarily, as shown in FIG. 1 and FIG. 15, the distance H4 between the black film layer 4 and the substrate 1 is greater than the distance H61 between the surface of the side of the first convex portion 31 away from the substrate 1 and the substrate 1, so that the black film layer 4 can cover the first convex portion 31, thereby avoiding exposing the first convex portion 31 outside the black film layer 4, and avoiding a large difference between the reflectivity of the display panel at the position where the first convex portion 31 is located and the reflectivity at other positions. In some embodiments, as shown in FIG. 15, a distance H4 between the black film layer 4 and the substrate 1 is greater than a distance H62 between a surface of the second convex portion 32 away from the substrate 1 and the substrate 1. In this way, the black film layer 4 can cover the second convex portion 32, so that the second convex portion 32 can be prevented from being exposed outside the black film layer 4, thereby avoiding a large difference between the reflectivity of the display panel at the position where the second convex portion 32 is located and the reflectivity at other positions, which is beneficial to improving the display effect of the display panel.

It should be noted that the cross-sectional shape of the second convex portion 32 perpendicular to the plane where the substrate 1 is located as shown in FIG. 15 is merely illustrative, and the shape of the second convex portion 32 may also be designed as a sphere, a pyramid or an irregular shape in some embodiments of the present disclosure.

Exemplarily, the first convex portion 31 and the second convex portion 32 include non-hydrophobic materials, for example, the first convex portion 31 and the second convex portion 32 include hydrophilic materials.

It should be noted that, in the present disclosure, the black film layer represents a film layer with a high light absorption rate, and not only the black film layer is considered to be a pure black substance in a narrow sense, and optionally, the light absorption rate of the black film layer to visible light is greater than or equal to 85%.

An embodiment of the present disclosure further provides a display device, as shown in FIG. 16, which is a schematic diagram of a display device according to an embodiment of the present disclosure, and the display device includes the above display panel 100. The specific structure of the display panel 100 has been described in detail in the foregoing embodiments, and details are not described herein again. The display apparatus shown in FIG. 16 is merely illustrative, and the display devices may be any electronic apparatus with a display function, such as a mobile phone, a tablet computer, a notebook computer, an electronic paper book, or a television.

Exemplarily, the display device may include a plurality of display panels 100 formed by splicing, so that the display area of the display device may be adjusted according to different design requirements.

The above description is only a preferred embodiment of the present disclosure and is not intended to limit the present disclosure, and any modifications, equivalent substitutions, improvements and the like made within the spirit and principle of the present disclosure should be included within the scope of the present disclosure.

What is claimed is:

1. A display panel, comprising:
a substrate having a display area;
wherein the display area comprises micro light emitting devices, a first convex portion and a black film layer located on a same side of the substrate, and
wherein at least part of an orthographic projection of the black film layer on a plane of the substrate is located between orthographic projections of two adjacent micro light emitting devices of the micro light emitting devices on the plane of the substrate.

2. The display panel according to claim 1, comprising pixel unit groups arranged along a first direction and a second direction, wherein
a pixel unit group of the pixel unit groups comprises two pixel row groups arranged along the second direction, a pixel row group of the two pixel row groups comprises two pixel units arranged along the first direction, a pixel unit of the two pixel units comprises at least two micro light emitting devices of different colors arranged along the first direction; and
the first direction and the second direction intersect with each other.

3. The display panel according to claim 2, wherein
the display area comprises a first convex portion group, the first convex portion group comprises at least one first convex portion, and the first convex portion group has a same distance to four pixel units in the pixel unit group.

4. The display panel according to claim 3, wherein
the first convex portion group comprises at least two first convex portions arranged along the first direction, and
a distance between two adjacent first convex portions in the first convex portion group is equal to a distance between two adjacent micro light emitting devices in a corresponding pixel unit.

5. The display panel according to claim 2, wherein
the display area further comprises a second convex portion group located between two pixel units in a same pixel row group, and
the second convex portion group has a same distance to the two pixel units in the same pixel row group; and the second convex portion group comprises at least one first convex portion.

6. The display panel according to claim 5, wherein
the second convex portion group comprises at least two first convex portions arranged along the first direction, and
a distance between two adjacent first convex portions in the second convex portion group is equal to a distance between two adjacent micro light emitting devices in a corresponding pixel unit.

7. The display panel according to claim 2, wherein
the display area further comprises a third convex portion group, the third convex portion group is located between two adjacent pixel units in the second direction in two adjacent pixel row groups, the third convex portion group has a same distance to the two pixel row groups, and the third convex portion group comprises at least one first convex portion;
wherein the third convex portion group comprises at least two first convex portions arranged along the first direction, and
wherein a distance between two adjacent first convex portions in the third convex portion group is equal to a distance between two adjacent micro light emitting devices in a corresponding pixel unit.

8. The display panel according to claim 2, wherein
the display area further comprises a fourth convex portion group, the fourth convex portion group comprises at least one first convex portion, the first convex portion in the fourth convex portion group is located between two adjacent micro light emitting devices in one pixel unit, and the fourth convex portion group has a same distance to each micro light emitting device of the two adjacent micro light emitting devices in the pixel unit.

9. The display panel according to claim 2, wherein,
a distance d12 between the first convex portion and a micro light emitting device that is nearest to the first convex portion in the first direction satisfies: W1/4≤d12≤B/2−W1;
a distance d11 between the first convex portion and the micro light emitting device that is nearest to the first convex portion in the second direction satisfies: L1/4≤d11≤A1/2−L1;
where
A1 is a distance between centers of two adjacent pixel units in the second direction;
B is a distance between centers of two adjacent pixel units in the first direction;
L1 is a length of a single micro light emitting device in the second direction; and
W1 is a length of a single micro light emitting device in the first direction.

10. The display panel according to claim 9, wherein,
d12=a1, where a1 is a distance between two adjacent micro light emitting devices in the pixel unit in the first direction.

11. The display panel according to claim 2, wherein
a length of the pixel unit in the first direction is W3, a length of the pixel unit in the second direction is L3, a length of the micro light emitting device in the first direction is W1, and a length of the micro light emitting device in the second direction is L1;
a length of the first convex portion in the first direction is W2, and a length of the first convex portion in the second direction is L2, and
W1/2≤W2≤W3; L1/2≤L2≤L3.

12. The display panel according to claim 1, wherein,
the display area further comprises a redundant position corresponding to the micro light emitting device;
the first convex portion is arranged between two adjacent redundant positions; or
the first convex portion is arranged between the redundant position and an adjacent micro light emitting device.

13. The display panel according to claim 1, further comprising a planarization layer located between the micro light emitting device and the substrate, wherein
a distance between a surface of the micro light emitting device away from the planarization layer and the planarization layer is H1, and a distance between a surface of the first convex portion away from the planarization layer and the planarization layer is H2, where H1/3≤H2≤H1/2.

14. The display panel according to claim 1, wherein,
the substrate further comprises a non-display area, the non-display area comprises a second convex portion, and the second convex portion and the first convex portion are arranged in a same layer.

15. The display panel according to claim 14, wherein
a distance d2 between the second convex portion and an edge of the display panel satisfies 10 μm≤d2≤20 μm.

16. The display panel according to claim 15, wherein
the non-display area comprises fifth convex portion groups arranged along a direction from the non-display area towards the display area, and each fifth convex portion group of the fifth convex portion groups comprises second convex portions arranged along an extension direction of an edge of the display panel.

17. The display panel according to claim 16, wherein,
one second convex portion in the fifth convex portion group at least partially overlaps, in a third direction, with two second convex portions that are nearest to the one second convex portion in the adjacent fifth convex portion group, and the third direction is parallel to a direction from the display area towards the non-display area.

18. The display panel according to claim 15, further comprising a planarization layer located between the micro light emitting device and the substrate,
Wherein a distance between a surface of the second convex portion away from the planarization layer and the planarization layer is less than or equal to half of a distance between a surface of the micro light emitting device away from the planarization layer and the planarization layer.

19. The display panel according to claim 14, wherein
a distance between the black film layer and the substrate is less than or equal to a distance between a surface of a side of the micro light emitting device away from the substrate and the substrate; and
the distance between the black film layer and the substrate is greater than a distance between a surface of the first convex portion away from the substrate and the substrate; or, the distance between the black film layer and the substrate is greater than a distance between a surface of the second convex portion away from the substrate and the substrate.

20. A display device, comprising a display panel, wherein the display panel comprises:
a substrate having a display area;
wherein the display area comprises micro light emitting devices, a first convex portion and a black film layer located on a same side of the substrate, and
wherein at least part of an orthographic projection of the black film layer on a plane of the substrate is located between orthographic projections of two adjacent micro light emitting devices of the micro light emitting devices on the plane of the substrate.
